(19) United States
(12) Patent Application Publication
(10) Pub. No.: US 2026/0237331 A1
(43) Pub. Date: Aug. 13, 2026

(54) DISPLAY PANEL, CRACK DETECTION METHOD THEREOF, AND ELECTRONIC DEVICE

(71) Applicant: Wuhan Tianma Micro-Electronics Co., Ltd., Wuhan (CN)

(72) Inventor: Xiaole LIU, Wuhan (CN)

(21) Appl. No.: 19/221,943

(22) Filed: May 29, 2025

(30) Foreign Application Priority Data
Feb. 10, 2025 (CN) 202510147066.1

(51) Int. Cl. G09G 3/00; H01L 25/16; H10D 86/40; H10D 86/60; H10H 29/49; H10H 29/853

(52) U.S. Cl. CPC G09G 3/006; H10D 86/481; H10D 86/60; H10H 29/49; H10H 29/853; H10W 90/00; G09G 2330/12

(57) ABSTRACT

The present disclosure discloses a display panel. The display panel includes: a substrate, and a crack detection circuit located on one side of the substrate. The crack detection circuit includes at least two crack detection lines sequentially arranged in a first direction, and adjacent crack detection lines of the at least two crack detection lines are insulated from each other. Any one crack detection line of the at least two crack detection lines has at least a partially overlapping region with at least one other crack detection line of the at least two crack detection lines in the first direction, where the first direction is perpendicular to a plane of the display panel.

### CROSS-REFERENCES TO RELATED APPLICATIONS

The present disclosure claims priority to Chinese Patent Application No. 202510147066.1, filed on Feb. 10, 2025, the content of which is incorporated herein by reference in its entirety.

### TECHNICAL FIELD

The present disclosure relates to the field of display technologies, and more particularly, relates to a display panel, a crack detection method thereof, and an electronic device.

### BACKGROUND

With the rapid development of display technologies, display panels have been increasingly applied in a plurality of technical fields. Currently, during the manufacturing process of display panels, cracks may be generated at the edges of the display panel. Cracks located at the edges may cause disconnection of routing lines near the bezel of the display panel. Furthermore, when a crack extends from the edge into the display region, it may adversely affect routing lines or circuits within the display region, thereby introducing a high risk of display defects such as dark spots or image anomalies.

In other words, edge cracks of the display panel may significantly impair the performance of the display panel. Accordingly, panel crack detection (PCD) conducted prior to shipment of the display panel becomes a critical step. However, in existing technologies, the panel crack detection performance of display panels is not ideal, and improvements in detection structures and manufacturing processes are required.

### SUMMARY

One aspect of the present disclosure provides a display panel. The display panel includes: a substrate, and a crack detection circuit located on one side of the substrate. The crack detection circuit includes at least two crack detection lines sequentially arranged in a first direction, and adjacent crack detection lines of the at least two crack detection lines are insulated from each other. Any one crack detection line of the at least two crack detection lines has at least a partially overlapping region with at least one other crack detection line of the at least two crack detection lines in the first direction, where the first direction is perpendicular to a plane of the display panel.

Another aspect of the present disclosure provides an electronic device. The electronic device includes a display panel, where the display panel includes: a substrate, and a crack detection circuit located on one side of the substrate. The crack detection circuit includes at least two crack detection lines sequentially arranged in a first direction, and adjacent crack detection lines of the at least two crack detection lines are insulated from each other. Any one crack detection line of the at least two crack detection lines has at least a partially overlapping region with at least one other crack detection line of the at least two crack detection lines in the first direction, where the first direction is perpendicular to a plane of the display panel.

Yet another aspect of the present disclosure provides a crack detection method for a display panel. The crack detection method includes: applying a capacitance detection signal to two crack detection lines having at least a partially overlapping region and obtaining a detection capacitance between the two crack detection lines; and determining whether a film layer in an overlapping region between the two crack detection lines has a crack based on a difference between the detection capacitance and a predetermined capacitance.

### BRIEF DESCRIPTION OF THE DRAWINGS

In order to more clearly illustrate the technical solutions of embodiments of the present disclosure, a brief description of the drawings required in the embodiments is provided below. It is evident that the drawings described below are merely embodiments of the present disclosure. Those of ordinary skill in the art may derive other drawings based on the provided drawings without inventive effort.

FIG. 1 illustrates a schematic structural diagram of a display panel according to some embodiments of the present disclosure;

FIG. 2 illustrates a cross-sectional view along direction B-B′ in FIG. 1;

FIG. 3 illustrates a schematic structural diagram of another display panel according to some embodiments of the present disclosure;

FIG. 4 illustrates a schematic structural diagram of yet another display panel according to some embodiments of the present disclosure;

FIG. 5 illustrates a schematic structural diagram of yet another display panel according to some embodiments of the present disclosure;

FIG. 6 illustrates a schematic structural diagram of yet another display panel according to some embodiments of the present disclosure;

FIG. 7 illustrates a cross-sectional view along direction C-C′ in FIG. 6;

FIG. 8 illustrates a schematic structural diagram of yet another display panel according to some embodiments of the present disclosure;

FIG. 9 illustrates a schematic structural diagram of yet another display panel according to some embodiments of the present disclosure;

FIG. 10 illustrates a schematic structural diagram of yet another display panel according to some embodiments of the present disclosure;

FIG. 11 illustrates a schematic structural diagram of yet another display panel according to some embodiments of the present disclosure;

FIG. 12 illustrates a schematic structural diagram of yet another display panel according to some embodiments of the present disclosure;

FIG. 13 illustrates a schematic structural diagram of yet another display panel according to some embodiments of the present disclosure;

FIG. 14 illustrates a schematic structural diagram of yet another display panel according to some embodiments of the present disclosure;

FIG. 15 illustrates a schematic structural diagram of yet another display panel according to some embodiments of the present disclosure;

FIG. 16 illustrates a schematic structural diagram of yet another display panel according to some embodiments of the present disclosure;

FIG. 17 illustrates a cross-sectional view along direction D-D′ in FIG. 16;

FIG. 18 illustrates a schematic structural diagram of yet another display panel according to some embodiments of the present disclosure;

FIG. 19 illustrates a schematic structural diagram of yet another display panel according to some embodiments of the present disclosure;

FIG. 20 illustrates a schematic structural diagram of yet another display panel according to some embodiments of the present disclosure;

FIG. 21 illustrates a flowchart of a crack detection method according to some embodiments of the present disclosure;

FIG. 22 illustrates a flowchart of another crack detection method according to some embodiments of the present disclosure;

FIG. 23 illustrates a schematic structural diagram of a pixel circuit according to some embodiments of the present disclosure; and

FIG. 24 illustrates a schematic structural diagram of an electronic device according to some embodiments of the present disclosure.

### REFERENCE NUMERALS

10—Substrate; 101—Semiconductor layer; 102—Gate insulating layer; 103—Gate metal layer; 104—Capacitor insulating layer; 105—Capacitor metal layer; 106—Interlayer insulating layer; 107—Source/drain metal layer; 108—Planarization layer; 20—Crack detection line; 21—First crack detection line; 22—Second crack detection line; 23—Edge crack detection line; 24—Opening crack detection line; 201—First detection line; 202—Second detection line; 203—Main detection block; 204—Auxiliary detection block; 30—Insulating isolation film layer; 31—Crack; 41—Anode layer; 42—Light-emitting layer; 43—Cathode layer; 50—Pixel definition layer; 60—Encapsulation structure layer; 61—First inorganic film; 62—Organic film; 63—Second inorganic film; 71—First touch metal layer; 72—Touch insulating layer; 73—Second touch metal layer; 74—Connection lead-out line; 80—Moisture barrier portion; Z—First direction; S1—Overlapping region; AA—Display region; HL—Opening region; NA—Non-display region; NA1—Scan line region; NA2—Chip bonding region; NA3—Top region; NA4—Bending region; T101—First transistor; T102—Second transistor; T103—Third transistor; T104—Fourth transistor; T105—Fifth transistor; T106—Sixth transistor; T107—Seventh transistor; C101—Storage capacitor; SCAN101—First scan signal terminal; SCAN102—Second scan signal terminal; EMIT—Emission control signal terminal; DATA—Data signal terminal; PVDD—Power voltage terminal; PVEE—Cathode voltage terminal; VREF—Reference voltage terminal; N101—First node; N102—Second node; and D101—Light-emitting diode.

### DETAILED DESCRIPTION

The technical solutions of the embodiments of the present disclosure will now be clearly and fully described with reference to the accompanying drawings. It is apparent that the embodiments described herein represent only a portion of the embodiments of the present disclosure, and not all embodiments. Based on the embodiments disclosed herein, all other embodiments that may be conceived by those of ordinary skill in the art without inventive effort shall fall within the scope of protection of the present disclosure.

As discussed in the background section, with the rapid development of display technologies, display panels have been increasingly applied in a plurality of technical fields. Currently, during the manufacturing process of display panels, cracks may be generated at the edges of the display panel. Cracks located at the edges may cause disconnection of routing lines near the bezel of the display panel. Furthermore, when a crack extends from the edge into the display region, the crack may adversely affect routing lines or circuits within the display region, thereby introducing a high risk of display defects such as dark spots or image anomalies. In other words, edge cracks of the display panel may significantly impair the performance of the display panel. Accordingly, panel crack detection performed prior to shipment of the display panel becomes a critical step. However, in existing technologies, the panel crack detection performance of display panels is not ideal, and improvements in detection structures and manufacturing processes are required.

In view of the foregoing, some embodiments of the present disclosure provide a display panel, a crack detection method for the display panel, and an electronic device, which effectively address the technical challenges of the related art and improve the performance of crack detection for the display panel.

To achieve the above objective, some embodiments of the present disclosure provide the following technical solutions, which will be described in detail below with reference to FIGS. 1 to 22.

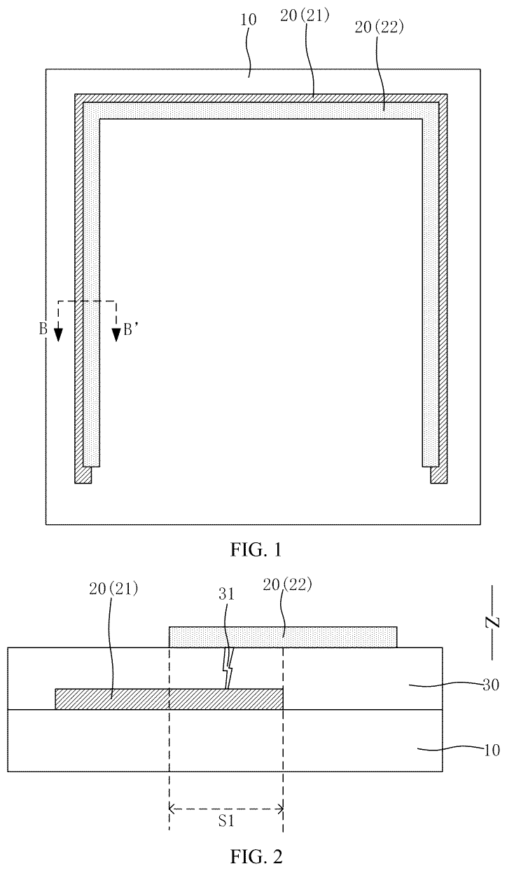

Referring to FIGS. 1 and 2, FIG. 1 illustrates a schematic structural diagram of a display panel according to some embodiments of the present disclosure, and FIG. 2 illustrates a cross-sectional view along direction B-B′ in FIG. 1. In some embodiments of the present disclosure, the display panel includes: a substrate 10, and a crack detection circuit located on one side of the substrate 10. The crack detection circuit includes at least two crack detection lines 20 sequentially arranged in a first direction Z, and adjacent crack detection lines 20 are electrically insulated from each other. In the first direction Z, any one of the crack detection lines 20 and at least one of the remaining crack detection lines 20 share at least a partially overlapping region. The first direction Z is a direction perpendicular to the plane of the display panel. Among the at least two crack detection lines 20, the extension directions of the two crack detection lines 20 may be the same. Along the extension direction, the two crack detection lines 20 may have an overlapping region in the first direction Z at any location.

Continuing with FIGS. 1 and 2, for illustrative purposes, the display panel is shown to include two crack detection lines 20. The two crack detection lines 20 are respectively a first crack detection line 21 and a second crack detection line 22. The first crack detection line 21 and the second crack detection line 22 have at least a partially overlapping region S1 in the first direction Z. In the first direction Z, an insulating isolation film layer 30 is provided between the first crack detection line 21 and the second crack detection line 22 to electrically isolate them. The insulating isolation film layer 30 is the layer to be inspected for the presence of a crack 31. The insulating isolation film layer 30 may be a single insulating structural layer, or a stack of a plurality of insulating structural layers, or a stack of insulating and metal structural layers. The present disclosure does not impose specific limitations on this configuration. The capacitance is related to the area of the capacitor plates, the distance between the plates, and the dielectric constant of the material layer between the plates. Using the crack detection circuit to detect cracks, when the insulating isolation film layer 30 has a crack 31 in the overlapping region between the first crack detection line 21 and the second crack detection line 22, the presence of the crack 31 in the insulating isolation film layer 30 effectively alters its dielectric constant, thereby causing a change in the capacitance between the first crack detection line 21 and the second crack detection line 22. When there is no crack 31 in the insulating isolation film layer 30 in the overlapping region between the first crack detection line 21 and the second crack detection line 22, the capacitance between the first crack detection line 21 and the second crack detection line 22 remains at a standard preset value. Therefore, the presence or absence of cracks in the insulating isolation film layer 30 may be determined based on variations in the capacitance between the first crack detection line 21 and the second crack detection line 22.

As evident from the above description, according to some embodiments of the present disclosure, the crack detection circuit includes crack detection lines 20 that are at least partially overlapping in the first direction. Accordingly, when using the crack detection circuit for crack detection, the capacitance variation between two overlapping crack detection lines 20 may be used to determine whether the film layer between them contains a crack, thereby completing the crack detection process for the display panel. The technical solution according to some embodiments of the present disclosure enables detection of cracks in the intermediate film layer between different crack detection lines 20, thereby improving the crack detection performance of the display panel. Moreover, the crack detection line structure according to some embodiments of the present disclosure is simple and occupies only a small portion of the available wiring area on the display panel.

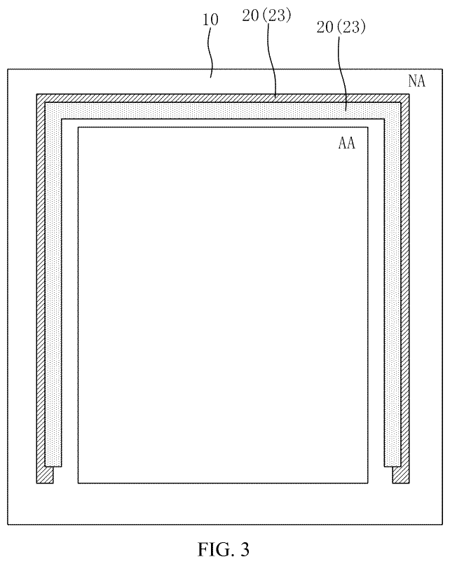

In some embodiments, the crack detection circuit according to some embodiments of the present disclosure may include a circuit located at the edge of the display panel. It is understood that cracks tend to occur at the edges of the display panel. On one hand, such cracks may be caused by cutting stress generated during the panel singulation process. On the other hand, for flexible display panels, bending the panel beyond the tolerable curvature radius of the flexible substrate may also lead to edge cracks. Therefore, the technical solution according to some embodiments of the present disclosure sets the crack detection circuit at the edge of the display panel, thereby enabling detection of cracks at the panel edge. Referring to FIG. 3, FIG. 3 illustrates a schematic structural diagram of another display panel according to some embodiments of the present disclosure. The display panel includes: a display region AA, and a non-display region NA located outside the display region AA. The non-display region NA may be located on one side of the display region AA, or the non-display region NA may be located on at least two sides of the display region AA, or the non-display region NA may be arranged around the display region AA as shown in FIG. 3. The present disclosure does not impose specific limitations on this arrangement. In some embodiments of the present disclosure, the crack detection line 20 includes an edge crack detection line 23 located in the non-display region NA. Any two edge crack detection lines 23 are electrically insulated from each other in the first direction Z. The edge crack detection lines 23 are configured to extend along the edge of the display region AA. Any one of the edge crack detection lines 23 shares at least a partially overlapping region in the first direction Z with at least one of the remaining edge crack detection lines 23. When using the edge crack detection line 23 for crack detection, the capacitance variation between two overlapping edge crack detection lines 23 may be used to determine whether a crack exists in the intermediate film layer between them, thereby enabling detection of cracks in the intermediate layer between different edge crack detection lines 23 and improving the performance of crack detection for the display panel.

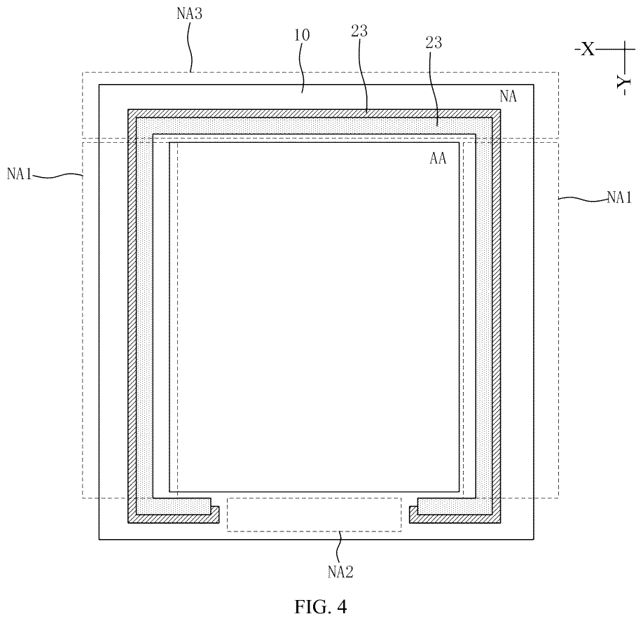

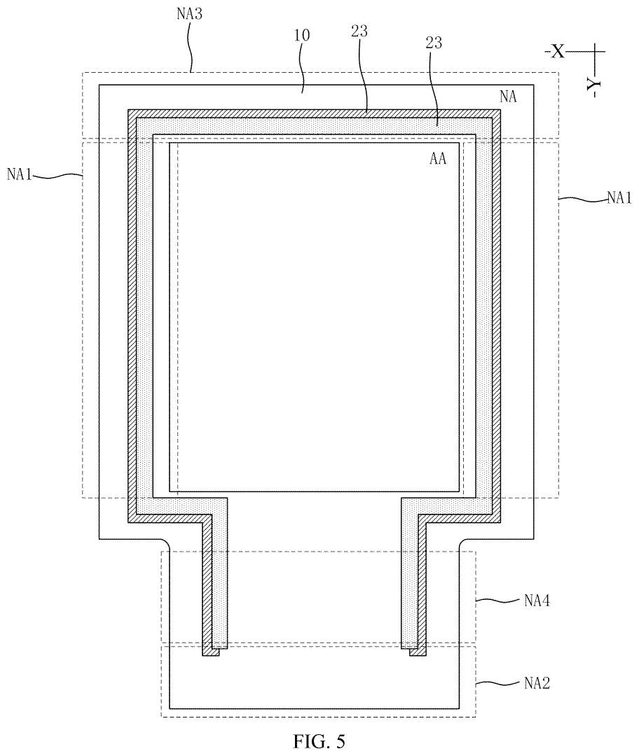

FIG. 4 illustrates a schematic structural diagram of yet another display panel according to some embodiments of the present disclosure. Referring to FIG. 4, the non-display region NA of the display panel includes, in a direction X, a scan line region NA1 located on at least one side of the display region AA. In a direction Y, the non-display region NA includes a chip bonding region NA2 and a top region NA3 on the opposite side. The edge crack detection line 23 is arranged to extend in a direction surrounding the display region AA, and includes at least a portion located at the scan line region NA1. The edge crack detection line 23 further extends toward the chip bonding region NA2. In addition, the edge crack detection line 23 may also extend to the top region NA3 on the opposite side of NA2, thereby increasing the detection coverage of the crack detection line and further improving the crack detection performance of the display panel. Further, FIG. 5 illustrates a schematic structural diagram of yet another display panel according to some embodiments of the present disclosure. Referring to FIG. 5, the non-display region NA further includes a bending region NA4 located between the chip bonding region NA2 and the display region AA. The bending region NA4 is configured to allow the chip bonding region NA2 to be bent toward the backside of the substrate 10 (the back side of the substrate 10, i.e., the surface of the substrate 10 opposite to the side where the crack detection line is arranged). Accordingly, by providing the bending region NA4, the wiring area of the non-display region NA may be increased without affecting the narrow bezel design of the display panel. Since cracks are likely to occur in the bending region NA4, according to some embodiments of the present disclosure, the edge crack detection line 23 may further extend to the bending region NA4, thereby enabling crack detection in the bending region NA4. As disclosed, the edge crack detection line 23 may further extend into the chip bonding region NA2, thereby facilitating electrical connection with a chip arranged in the chip bonding region NA2 and allowing the chip to provide a detection signal to the edge crack detection line 23.

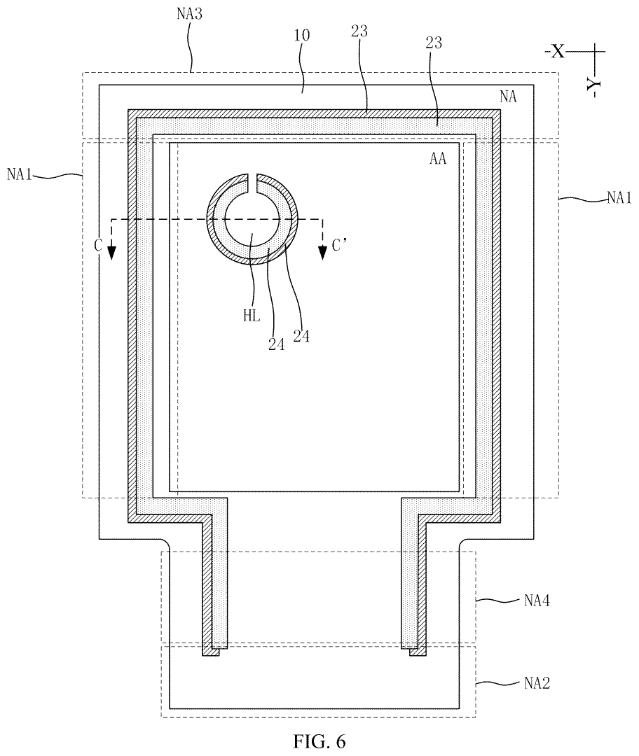

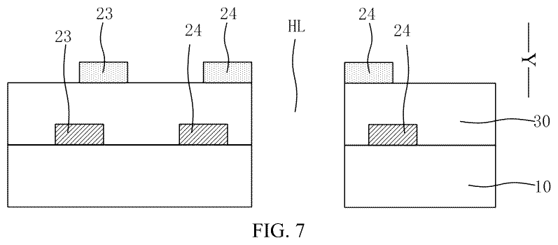

In some embodiments of the present disclosure, the crack detection circuit may further include a circuit located in an opening region HL of the display panel. To improve the screen-to-body ratio of the display panel, an opening may be formed in the display region AA to accommodate an optical component such as a camera in the opening region HL. During the manufacturing process of the display panel, cracks may easily occur during the formation of the opening region HL, and when such cracks extend into the display region AA, dark spots may appear on the display panel, thereby affecting the service life of the display panel. Accordingly, the technical solution according to some embodiments of the present disclosure includes a crack detection line arranged in the opening region HL, enabling crack detection in the opening region HL of the display panel. Referring to FIGS. 6 and 7, FIG. 6 is a schematic structural diagram of another display panel according to some embodiments of the present disclosure, and FIG. 7 is a cross-sectional view along the direction C-C′ in FIG. 6. As shown, the display panel includes an opening region HL within the display region AA. The crack detection line 20 includes an opening crack detection line 24 located in the display region AA. Any two opening crack detection lines 24 are electrically insulated from each other in the first direction Z. The opening crack detection lines 24 are arranged to surround the opening region HL. Any one of the opening crack detection lines 24 shares at least a partially overlapping region in the first direction Z with at least one of the remaining opening crack detection lines 24.

It should be noted that, according to some embodiments of the present disclosure, when the display panel includes a display region AA and a non-display region NA, the crack detection circuit may include an edge crack detection line 23 arranged in the non-display region NA. When the display panel includes a display region AA, a non-display region NA, and an opening region HL located within the display region AA, the crack detection circuit may include only an edge crack detection line 23 arranged in the non-display region NA, or only an opening crack detection line 24 arranged in the opening region HL, or both an edge crack detection line 23 in the non-display region NA and an opening crack detection line 24 in the opening region HL. The present disclosure does not impose specific limitations in this regard. In addition, in some other embodiments, the crack detection circuit may include a crack detection line 20 arranged in other regions of the display panel, which may be specifically designed according to actual applications.

In some embodiments, the crack detection lines 20 may include continuous detection lines, thereby simplifying the fabrication process of the crack detection circuit. Alternatively, the crack detection lines 20 may include non-continuous detection lines, where the crack detection lines 20 are segmented, and the presence of a crack may be accurately determined based on the capacitance detection results corresponding to each segment. The present disclosure does not impose specific limitations in this regard. As shown in FIG. 6, at least one of the crack detection lines 20 may be a continuous detection line, thereby simplifying the fabrication process of the crack detection line 20. When at least one of the crack detection lines 20 is an edge crack detection line 23, the edge crack detection line 23 may start from the chip bonding region NA2, continuously extend around the display region AA, and then return to the chip bonding region NA2. This edge crack detection line 23 is a continuous detection line without any breaks along its extending path. Alternatively, when at least one of the crack detection lines 20 is an opening crack detection line 24, the opening crack detection line 24 may continuously extend around the opening region HL in a direction surrounding the opening region HL. This opening crack detection line 24 is a continuous detection line without any breaks along its extending path.

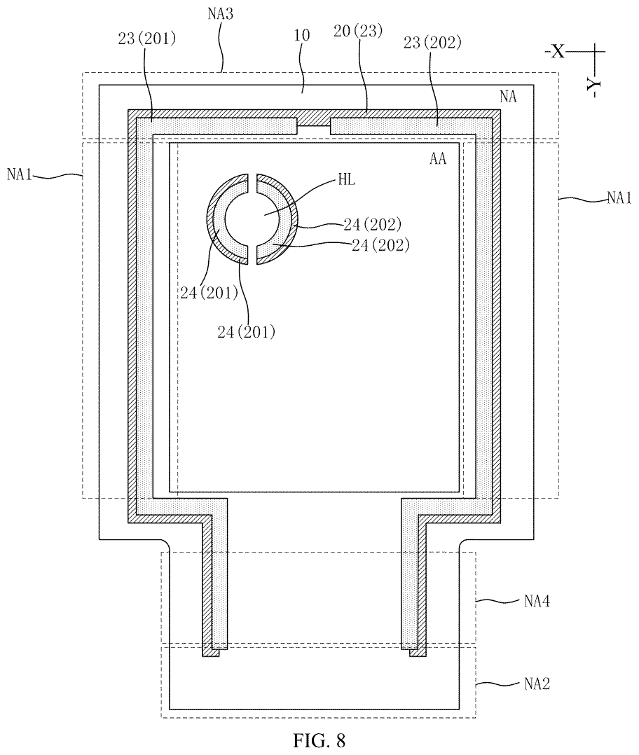

FIG. 8 illustrates a schematic structural diagram of yet another display panel according to some embodiments of the present disclosure. Referring to FIG. 8, at least one of the crack detection lines 20 includes a first detection line 201 and a second detection line 202 segmented along the extending direction of the crack detection line 20. The first detection line 201 shares at least a partially overlapping region in the first direction Z with at least one of the remaining crack detection lines 20, and the second detection line 202 also shares at least a partially overlapping region in the first direction Z with at least one of the remaining crack detection lines 20. It is understood that the crack detection line 20 may be segmented into the first detection line 201 and the second detection line 202. When the crack detection circuit is used for crack detection, it is possible to detect whether a crack exists in the film layer between the first detection line 201 and another crack detection line 20 that overlaps with the first detection line 201 in the first direction Z. Similarly, it is possible to detect whether a crack exists in the film layer between the second detection line 202 and another crack detection line 20 that overlaps with the second detection line 202 in the first direction Z. In this manner, not only may cracks in the display panel be detected, but it is also possible to determine whether the crack specifically falls within the range of the first detection line 201 or the second detection line 202, thereby improving the crack detection performance.

In some embodiments, when the crack detection line 20 is segmented into the first detection line 201 and the second detection line 202, the crack detection line 20 that overlaps therewith in the first direction Z may be a continuous detection line. Continuing with the example shown in FIG. 8 and taking two edge crack detection lines 23 as an example, one of the edge crack detection lines 23 is segmented into a first detection line 201 and a second detection line 202 that semi-surround the display region AA, while the other edge crack detection line 23 is a continuous detection line. When such a crack detection circuit configuration is used for crack detection, it is possible to detect whether a crack exists in the film layer between the first detection line 201 of one edge crack detection line 23 and the other edge crack detection line 23. Similarly, it is possible to detect whether a crack exists in the film layer between the second detection line 202 of one edge crack detection line 23 and the other edge crack detection line 23. This allows for both edge crack detection of the display panel and for determining whether the crack occurs within the range of the first detection line 201 or the second detection line 202, thereby improving detection precision.

Alternatively, when the crack detection line 20 is segmented into the first detection line 201 and the second detection line 202, the other crack detection line 20 that overlaps therewith in the first direction Z may be a non-continuous detection line. Continuing with the example shown in FIG. 8, and taking two opening crack detection lines 24 as an example, one opening crack detection line 24 is segmented into a first detection line 201 and a second detection line 202 that semi-surround the display region AA, and the other opening crack detection line 24 is also segmented into a first detection line 201 and a second detection line 202 that semi-surround the display region AA. The two first detection lines 201 have an overlapping region in the first direction Z, and the two second detection lines 202 also have an overlapping region in the first direction Z. When such a crack detection configuration is used for crack detection, whether a crack exists in the film layer between the two first detection lines 201 may be determined based on the change in capacitance between them. Similarly, whether a crack exists between the two second detection lines 202 may also be detected based on a capacitance change. Not only may cracks in the opening region HL of the display panel be detected, but it is also possible to determine whether the crack specifically occurs within the range of the two first detection lines 201 or within the range of the two second detection lines 202, thereby improving the crack detection performance.

It should be noted that FIG. 8 illustrates an example in which one of the two edge crack detection lines 23 is segmented into the first detection line 201 and the second detection line 202, while the other edge crack detection line 23 is a continuous detection line. Additionally, both of the two opening crack detection lines 24 are segmented into the first detection line 201 and the second detection line 202. In some other embodiments, both of the two edge crack detection lines 23 may be segmented into the first detection line 201 and the second detection line 202. Likewise, among the two opening crack detection lines 24, one opening crack detection line 24 may be segmented into the first detection line 201 and the second detection line 202, while the other opening crack detection line 24 may remain a continuous detection line. The present disclosure does not impose specific limitations in this regard.

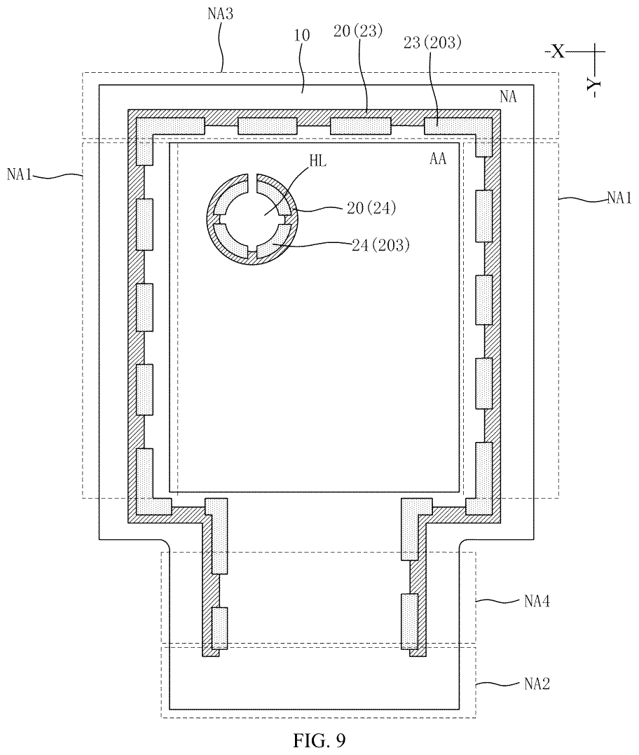

As disclosed in some embodiments, to further enhance crack localization accuracy, at least one crack detection line 20 may be further segmented into a greater number of detection blocks. FIG. 9 illustrates a schematic structural diagram of yet another display panel according to some embodiments of the present disclosure. Referring specifically to FIG. 9, among two crack detection lines 20 that share at least a partially overlapping region, one of the two crack detection lines 20 is segmented into a plurality of main detection blocks 203 along the extending direction of the crack detection line 20. The main detection blocks 203 have at least a partially overlapping region in the first direction Z with the other crack detection line 20. It is understood that the crack detection line 20 may be segmented into a greater number of main detection blocks 203 along the extending direction of the crack detection line 20. When the crack detection circuit is used for crack detection, each main detection block 203 may cooperate with a corresponding overlapping crack detection line 20 in the first direction Z to detect whether a crack exists in the intermediate film layer. This configuration not only enables crack detection of the display panel, but also enhances the ability to localize the specific main detection block 203 in which the crack appears, thereby further improving the crack detection accuracy.

Continuing with reference to FIG. 9, among two crack detection lines 20 having at least a partially overlapping region, one of the two crack detection lines 20 includes a plurality of main detection blocks 203 segmented along the extending direction of the crack detection line 20, and the other crack detection line 20 may be a continuous detection line. Taking two edge crack detection lines 23 as an example, one of the two edge crack detection line 23 is segmented into a plurality of main detection blocks 203 along the extending direction of the edge crack detection line 23, and the other edge crack detection line 23 is a continuous detection line. When such a crack detection configuration is used for crack detection, it is possible to detect whether a crack exists in the film layer between each main detection block 203 and the other edge crack detection line 23. This enables crack detection at the edge of the display panel and further allows for localization of the specific main detection block 203 where the crack occurs, thereby improving the crack detection performance. Similarly, taking two opening crack detection lines 24 as an example, one of the two opening crack detection lines 24 is segmented into a plurality of main detection blocks 203 along the extending direction of the opening crack detection line 24, and the other opening crack detection line 24 is a continuous detection line. When such a crack detection configuration is used for crack detection, it is possible to detect whether a crack exists in the film layer between each main detection block 203 and the other opening crack detection line 24. This enables crack detection in the opening region HL of the display panel and further allows for localization of the specific main detection block 203 where the crack occurs, thereby enhancing detection accuracy.

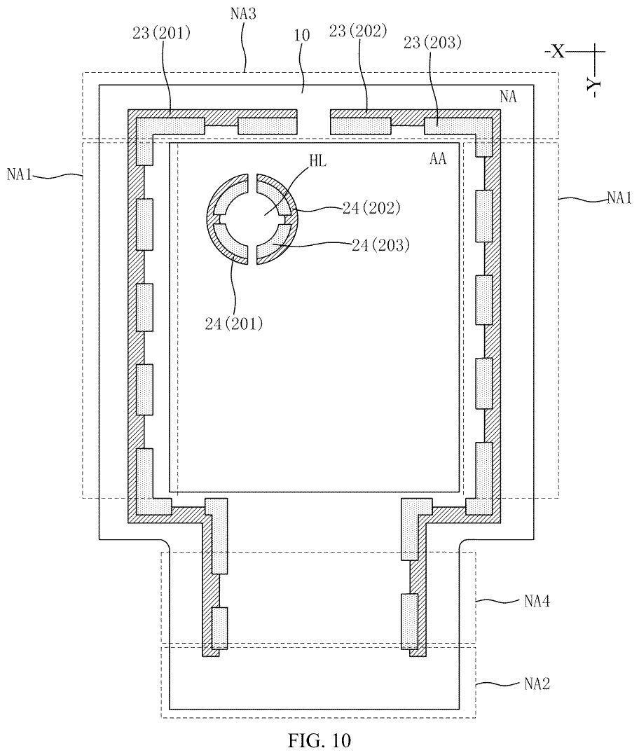

Alternatively, among two crack detection lines 20 having at least a partially overlapping region, when one of the two crack detection lines 20 is segmented into a plurality of main detection blocks 203 along the extending direction of the crack detection line 20, the other crack detection line 20 may also be segmented. Specifically, FIG. 10 illustrates a schematic structural diagram of yet another display panel according to some embodiments of the present disclosure. Referring to FIG. 10, among two crack detection lines 20 having at least a partially overlapping region, one of the two crack detection lines 20 includes a plurality of main detection blocks 203 segmented along the extending direction of the crack detection line 20, and the other crack detection line 20 includes a first detection line 201 and a second detection line 202 segmented along the extending direction of the other crack detection line 20. The first detection line 201 shares at least a partially overlapping region in the first direction Z with at least a portion of the main detection blocks 203, and the second detection line 202 shares at least a partially overlapping region in the first direction Z with the remaining portion of the main detection blocks 203. It is understood that the crack detection line 20 may be segmented into a greater number of main detection blocks 203 along the extending direction of the crack detection line 20, while the other crack detection line 20 may be segmented into a first detection line 201 and a second detection line 202. When such a crack detection configuration is used for crack detection, changes in capacitance between part of the main detection blocks 203 and the first detection line 201 may be used to determine whether a crack exists in the film layer between the two. Similarly, capacitance changes between the remaining main detection blocks 203 and the second detection line 202 may be used to detect whether a crack exists between the two. This configuration not only enables crack detection in the display panel, but also provides finer localization of the specific main detection block 203 where the crack occurs, further improving the detection performance. Moreover, segmenting the other crack detection line 20 into the first detection line 201 and the second detection line 202 may expand the applicability of the crack detection circuit to different display panel structures. For example, when a via or similar structure is present in the extending direction of the other crack detection line 20, the crack detection line 20 may be segmented at the location of the via into the first detection line 201 and the second detection line 202, thereby enhancing the adaptability of the crack detection design.

Continuing with reference to FIG. 10 and taking two edge crack detection lines 23 as an example, one of the two edge crack detection lines 23 is segmented into a plurality of main detection blocks 203 along the extending direction of the edge crack detection line 23, and the other edge crack detection line 23 is segmented into a first detection line 201 and a second detection line 202 along the extending direction of the other edge crack detection line 23. When this configuration is used for crack detection, changes in capacitance between part of the main detection blocks 203 and the first detection line 201 may be used to determine whether a crack exists in the film layer therebetween. Similarly, capacitance changes between the remaining main detection blocks 203 and the second detection line 202 may be used to detect whether a crack exists in the corresponding film layer. This configuration not only enables crack detection at the edge of the display panel but also allows for further localization of the crack to a specific main detection block 203, thereby enhancing detection accuracy. Likewise, taking two opening crack detection lines 24 as an example, one of the two opening crack detection line 24 is segmented into a plurality of main detection blocks 203 along the extending direction of the opening crack detection line 24, and the other opening crack detection line 24 is segmented into a first detection line 201 and a second detection line 202 along the extending direction of the other opening crack detection line 24. When this configuration is used for crack detection, it is possible to detect, through capacitance changes, whether cracks are present between the film layer located between the part of the main detection blocks 203 and the first detection line 201, and whether cracks are present between the remaining main detection blocks 203 and the second detection line 202. Not only may cracks in the opening region HL of the display panel be detected, but it is also possible to further localize the crack at the opening region HL to a specific main detection block 203 where the crack occurs, thereby further improving the crack detection performance.

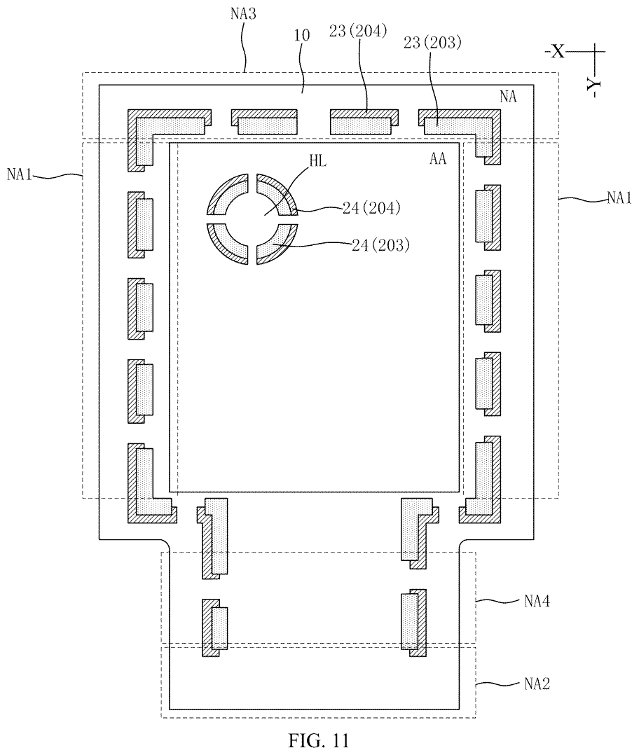

Alternatively, among two crack detection lines 20 having at least a partially overlapping region, when one of the two crack detection lines 20 is segmented into a plurality of main detection blocks 203 along the extending direction of the crack detection line 20, the other crack detection line 20 may also be segmented into a plurality of detection blocks 204. FIG. 11 illustrates a schematic structural diagram of yet another display panel according to some embodiments of the present disclosure. Referring specifically to FIG. 11, among two crack detection lines 20 having at least a partially overlapping region, one of the two crack detection line 20 is segmented into a plurality of main detection blocks 203 along the extending direction of the crack detection line 20, and the other crack detection line 20 is segmented into a plurality of auxiliary detection blocks 204 along the extending direction of the other crack detection line 20. One of the auxiliary detection block 204 shares at least a partially overlapping region in the first direction Z with a corresponding main detection block 203. It is understood that one crack detection line 20 may be segmented into a greater number of main detection blocks 203 along the extending direction of the crack detection line 20, while the other crack detection line 20 may be segmented into at least an equal number of auxiliary detection blocks 204. When such a crack detection configuration is used for crack detection, whether a crack exists in the film layer between each main detection block 203 and the corresponding overlapping auxiliary detection block 204 may be detected based on capacitance changes. This configuration enables crack detection of the display panel and further allows for precise localization of the specific main detection block 203 and auxiliary detection block 204 where the crack appears, thereby improving the crack detection resolution. Additionally, segmenting the other crack detection line 20 into a plurality of auxiliary detection blocks 204 also enhances the adaptability of the crack detection line structure to various types of display panels.

Continuing with reference to FIG. 11 and taking two edge crack detection lines 23 as an example, one of the two edge crack detection line 23 is segmented into a plurality of main detection blocks 203 along the extending direction of the edge crack detection line 23, and the other edge crack detection line 23 is segmented into a plurality of auxiliary detection blocks 204. When this crack detection configuration is employed, whether a crack exists between the film layer located between the main detection block 203 and the overlapping auxiliary detection block 204 may be determined based on capacitance variations. This allows for edge crack detection in the display panel and further enables crack localization within a specific overlapping pair of main detection block 203 and auxiliary detection block 204, thereby improving crack detection accuracy. Similarly, taking two opening crack detection lines 24 as an example, one of the two opening crack detection lines 24 is segmented into a plurality of main detection blocks 203, and the other opening crack detection line 24 is segmented into a plurality of auxiliary detection blocks 204. When such a crack detection configuration is used for crack detection, it is possible to determine, based on capacitance changes, whether a crack exists in the film layer between the main detection block 203 and the corresponding auxiliary detection block 204. This enables crack detection in the opening region HL and allows for finer localization of the crack within a particular overlapping pair of main detection blocks 203 and auxiliary detection block 204, thereby improving detection effectiveness.

It should be noted that the display panel as disclosed herein is not limited to the configurations of the edge crack detection lines 23 and the opening crack detection lines 24 respectively illustrated in FIGS. 9 and 10. The edge crack detection lines 23 and the opening crack detection lines 24 illustrated in FIGS. 9 and 10 may be arbitrarily combined, such as combining the edge crack detection lines 23 of FIG. 9 with the opening crack detection lines 24 of FIG. 10, or combining the edge crack detection lines 23 of FIG. 10 with the opening crack detection lines 24 of FIG. 11, and so forth. The present disclosure does not impose specific limitations in this regard and the design may be adapted according to actual application requirements.

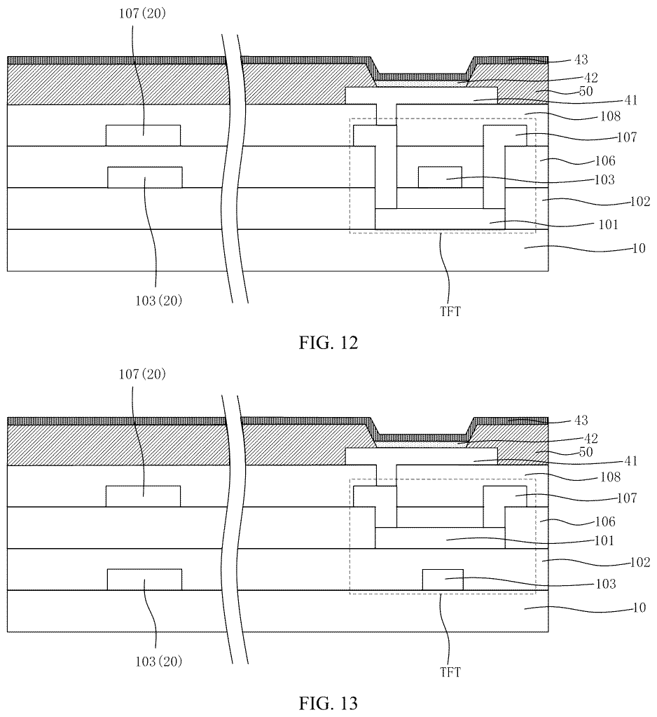

In some embodiments, the crack detection circuit as disclosed may be formed using a dedicated metal layer. Alternatively, the crack detection circuit may reuse an existing metal layer in the display panel. For example, the display panel as disclosed may include a transistor array layer located on a substrate 10, where the transistor array layer includes a gate metal layer 103 and a source/drain metal layer 107. The gate metal layer 103 and the source/drain metal layer 107 may respectively include one of the crack detection lines 20. FIG. 12 illustrates a schematic structural diagram of yet another display panel according to some embodiments of the present disclosure. Referring specifically to FIG. 12, the display panel may include circuits such as a pixel circuit and a scan driver circuit. The pixel circuit and the scan driver circuit may include structures such as transistors. The scan driver circuit is electrically connected to the pixel circuit and configured to provide a corresponding scan control signal to the pixel circuit. The pixel circuit is electrically connected to an anode block and configured to supply a drive signal to a light-emitting diode that includes the anode block, a light-emitting layer 42, and a cathode layer 43. Specifically, the display panel may include: a substrate 10; a transistor array layer located on the substrate 10, which includes a semiconductor layer 101 having an active region for forming a thin-film transistor (TFT); a gate insulating layer 102 located on a side of the semiconductor layer 101 facing away from the substrate 10; a gate metal layer 103 located on a side of the gate insulating layer 102 facing away from the substrate 10, where the gate metal layer 103 includes a gate electrode for forming the TFT; an interlayer insulating layer 106 located on a side of the gate metal layer 103 facing away from the substrate 10; a source/drain metal layer 107 located on a side of the interlayer insulating layer 106 facing away from the substrate 10, where the source/drain metal layer 107 includes a source and a drain for forming a transistor TFT, and the source and the drain are in contact with the active area through respective vias; and a planarization layer 108 located on a side of the source/drain metal layer 107 facing away from the substrate 10. In addition, the display panel includes: an anode layer 41, a pixel definition layer 50, a light-emitting layer 42, and a cathode layer 43. The anode layer 41 is located on a side of the planarization layer 108 facing away from the substrate 10, and includes a plurality of anode blocks, where the anode blocks are electrically connected to the source or drain electrode of a corresponding TFT in the pixel circuit through a via. The pixel definition layer 50 is located on a side of the anode layer 41 facing away from the substrate 10 and includes a plurality of pixel openings, and the pixel openings expose the anode blocks. The light-emitting layer 42 is located in the pixel openings and on a side of the anode layer 41 facing away from the substrate 10. The cathode layer 43 is located on a side of the light-emitting layer 42 facing away from the substrate 10. In some embodiments of the present disclosure, the gate metal layer 103 and the source/drain metal layer 107 respectively include one of the crack detection lines 20. The crack detection lines 20 are formed by reusing the gate metal layer 103 and the source/drain metal layer 107, such that there is no need to form a new metal layer separately for fabricating the crack detection lines, thereby simplifying the manufacturing process of the display panel and reducing production costs.

In the display panel shown in FIG. 12, the TFT is a top-gate type transistor, that is, the gate electrode is located above the active layer. In some other embodiments, the TFT may be a bottom-gate type transistor, that is, the gate electrode is located beneath the active region. Specially, FIG. 13 illustrates a schematic structural diagram of yet another display panel according to some embodiments of the present disclosure. Referring to FIG. 13, the display panel includes: a substrate 10, and a transistor array layer located on the substrate 10. The transistor array layer includes: a gate metal layer 103, a gate insulating layer 102, a semiconductor layer 101, an interlayer insulating layer 106, a source/drain metal layer 107, and a planarization layer 108. The gate metal layer 103 includes a gate electrode forming a transistor TFT. The gate insulating layer 102 is located on a side of the gate metal layer 103 facing away from the substrate 10. The semiconductor layer 101 is located on a side of the gate insulating layer 102 facing away from the substrate 10, and includes an active region for forming the TFT. The interlayer insulating layer 106 is located on a side of the semiconductor layer 101 facing away from the substrate 10. The source/drain metal layer 107 is located on a side of the interlayer insulating layer 106 facing away from the substrate 10, and includes a source and a drain forming a transistor TFT, where the source and the drain are in contact with the active area through respective vias. The planarization layer 108 is located on a side of the source/drain metal layer 107 facing away from the substrate 10. In addition, the display panel includes an anode layer 41, a pixel definition layer 50, a light-emitting layer 42, and a cathode layer 43. The anode layer 41 is located on a side of the planarization layer 108 facing away from the substrate 10, and includes a plurality of anode blocks. The anode blocks are electrically connected to the source or drain electrode of the corresponding TFT in the pixel circuit via vias. The pixel definition layer 50 is located on a side of the anode layer 41 facing away from the substrate 10 and includes a plurality of pixel openings that expose the anode blocks. The light-emitting layer 42 is located in the pixel openings and on a side of the anode layer 41 facing away from the substrate 10. The cathode layer 43 is located on a side of the light-emitting layer 42 facing away from the substrate 10. As disclosed herein, the gate metal layer 103 and the source/drain metal layer 107 respectively include one of the crack detection lines 20. The crack detection lines 20 are fabricated by reusing the gate metal layer 103 and the source/drain metal layer 107, Therefore, there is no need to fabricate a new metal layer separately for the crack detection lines, simplifying the manufacturing process of the display panel and reducing the overall production cost.

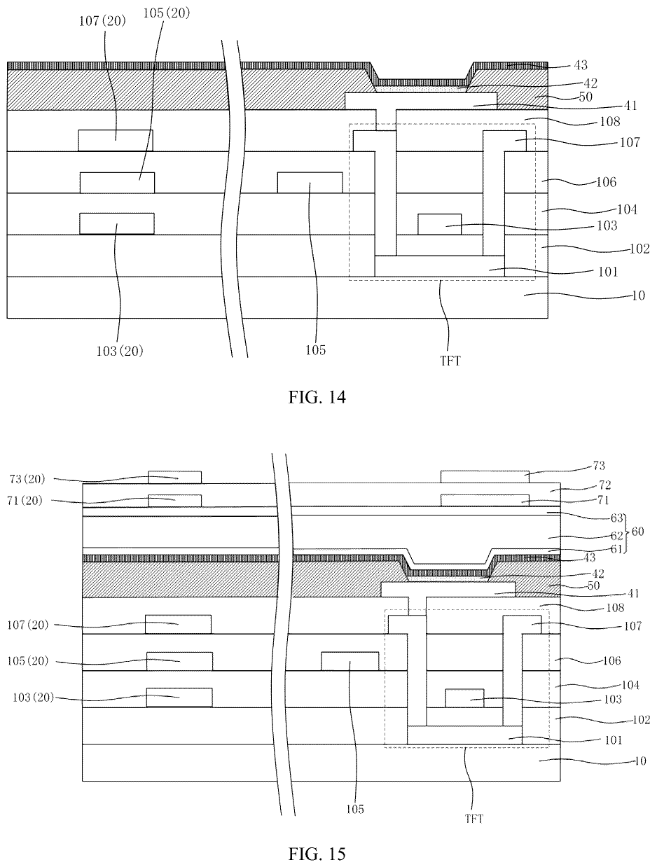

In some embodiments, the display panel may further include a capacitor metal layer 105 configured to form a capacitor, and the capacitor metal layer 105 may also include a crack detection line 20. Specifically, the display panel may include a transistor array layer located on the substrate 10, and the transistor array layer may include: a gate metal layer 103, a capacitor metal layer 105, and a source/drain metal layer 107. At least two of the gate metal layers 103, the capacitor metal layer 105, and the source/drain metal layer 107 include a crack detection line 20 respectively. FIG. 14 illustrates a schematic structural diagram of yet another display panel according to some embodiments of the present disclosure. Referring to FIG. 14 and taking the example of a top-gate TFT, the display panel includes: a substrate 10, and a transistor array layer located on the substrate 10. The transistor array layer includes: a semiconductor layer 101 with an active region for forming the TFT; a gate insulating layer 102 located on a side of the semiconductor layer 101 facing away from the substrate 10; a gate metal layer 103 located on a side of the gate insulating layer 102 facing away from the substrate, where the gate metal layer 103 includes a gate electrode for forming a transistor TFT; a capacitor insulating layer 104 located on a side of the gate metal layer 103 facing away from the substrate 10; and a capacitor metal layer 105 located on a side of the capacitor insulating layer 104 facing away from the substrate 10, where the capacitor metal layer 105 includes one plate of a capacitor in the circuit, and the other capacitor plate may be located in the gate metal layer 103 or the source/drain metal layer 107; an interlayer insulating layer 106 located on a side of the capacitor metal layer 105 facing away from the substrate 10; and a source/drain metal layer 107 located on a side of the interlayer insulating layer 106 facing away from the substrate 10, where the source/drain metal layer 107 includes a source and a drain for forming a transistor TFT, and the source and the drain are in contact with the active area through respective vias; and a planarization layer 108 located on a side of the source/drain metal layer 107 facing away from the substrate 10. In addition, the display panel includes: an anode layer 41 located on a side of the planarization layer 108 facing away from the substrate 10, where the anode layer 41 includes a plurality of anode blocks electrically connected to the source or drain electrode of the corresponding TFT in the pixel circuit; a pixel definition layer 50 located on a side of the anode layer 41 facing away from the substrate 10, where the pixel definition layer 50 includes a plurality of pixel openings that expose the anode blocks; a light-emitting layer 42 located in the pixel openings and on a side of the anode layer 41 facing away from the substrate 10; and a cathode layer 43 located on a side of the light-emitting layer 42 facing away from the substrate 10. As disclosed herein, at least two of the gate metal layer 103, the capacitor metal layer 105, and the source/drain metal layer 107, respectively include a crack detection line 20. The crack detection lines 20 are fabricated by reusing the gate metal layer 103, the capacitor metal layer 105, and the source/drain metal layer 107, such that there is no need to form additional metal layers, thereby simplifying the display panel fabrication process and reducing cost.

It should be noted that, when the transistor array layer, according to some embodiments of the present disclosure, includes the gate metal layer 103, the capacitor metal layer 105, and the source/drain metal layer 107, the gate metal layer 103 and the capacitor metal layer 105 each include a crack detection line 20; or, the gate metal layer 103 and the source/drain metal layer 107 each include a crack detection line 20; or, the capacitor metal layer 105 and the source/drain metal layer 107 each include a crack detection line 20; or, the gate metal layer 103, the capacitor metal layer 105 and the source/drain metal layer 107 each include a crack detection line 20. The specific configuration may be determined based on the actual application.

In some embodiments of the present disclosure, the display panel may further include a capacitor metal layer 105 for forming a capacitor and a touch metal layer for forming a touch electrode. The capacitor metal layer 105 and/or the touch metal layer may also include a crack detection line 20. That is, the display panel as disclosed may include a transistor array layer located on a substrate, where the transistor array layer includes a gate metal layer 103, a capacitor metal layer 105, and a source/drain metal layer 107. The display panel may further include at least one touch metal layer located on a side of the transistor array layer facing away from the substrate 10. At least two of the gate metal layer 103, the capacitor metal layer 105, the source/drain metal layer 107, and the touch metal layer respectively include one of the crack detection lines 20. Specially, FIG. 15 takes a top-gate thin-film transistor (TFT) as an example. Referring to FIG. 15, the display panel includes: a substrate 10, and a transistor array layer located on the substrate 10. The transistor array layer includes: a semiconductor layer 101 having an active region for forming the TFT; a gate insulating layer 102 located on a side of the semiconductor layer 101 facing away from the substrate 10; a gate metal layer 103 located on a side of the gate insulating layer 102 facing away from the substrate 10, where the gate metal layer 103 includes the gate electrode of the TFT; a capacitor insulating layer 104 located on a side of the gate metal layer 103 facing away from the substrate 10; a capacitor metal layer 105 located on a side of the capacitor insulating layer 104 facing away from the substrate 10, where the capacitor metal layer 105 includes one plate of a capacitor, and the other plate of the capacitor may be located in the gate metal layer 103 or in the source/drain metal layer 107; an interlayer insulating layer 106 located on a side of the capacitor metal layer 105 facing away from the substrate 10; a source/drain metal layer 107 located on a side of the interlayer insulating layer 106 facing away from the substrate 10, where the source/drain metal layer 107 includes source and drain electrodes for forming the TFT, and the source and drain electrodes are electrically connected to the active region through respective vias; and a planarization layer 108 located on a side of the source/drain metal layer 107 facing away from the substrate 10. In addition, the display panel includes: an anode layer 41 located on a side of the planarization layer 108 facing away from the substrate 10, where the anode layer 41 includes a plurality of anode blocks, and the plurality of anode blocks are electrically connected to the source or drain electrode of the corresponding TFT through vias; a pixel definition layer 50 located on a side of the anode layer 41 facing away from the substrate 10, where the pixel definition layer 50 includes a plurality of pixel openings that expose the anode blocks; a light-emitting layer 42 located in the pixel openings and on a side of the anode layer 41 facing away from the substrate 10; and a cathode layer 43 located on a side of the light-emitting layer 42 facing away from the substrate 10. The display panel further includes: an encapsulation structure layer 60 located on a side of the cathode layer 43 facing away from the substrate 10. The encapsulation structure layer 60 includes: a first inorganic film 61 located on a side of the cathode layer 43 facing away from the substrate 10; an organic film 62 located on a side of the first inorganic film 61 facing away from the substrate 10; and a second inorganic film 63 located on a side of the organic film 62 facing away from the substrate 10. The encapsulation structure serves to encapsulate the display panel and at least functions to prevent water vapor from corroding internal circuits of the display panel. The display panel may further include: at least one touch metal layer located on the encapsulation structure layer 60, such as a first touch metal layer 71 located on the encapsulation structure layer 60; a touch insulating layer 72 located on a side of the first touch metal layer 71 facing away from the substrate 10; and a second touch metal layer 73 located on a side of the touch insulating layer 72 facing away from the substrate 10. The display panel may also include: a protective layer located on a side of the second touch metal layer 73 facing away from the substrate 10. These structures will not be described in further detail. Among the gate metal layer 103, the capacitor metal layer 105, the source/drain metal layer 107, the first touch metal layer 71, and the second touch metal layer 73, at least two of these layers respectively include a crack detection line 20. The crack detection line 20 is formed by reusing one or more of the gate metal layer 103, the capacitor metal layer 105, the source/drain metal layer 107, the first touch metal layer 71, and the second touch metal layer 73. As a result, no additional metal layer is required to form the crack detection line, simplifying the fabrication process of the display panel and reduces manufacturing cost.

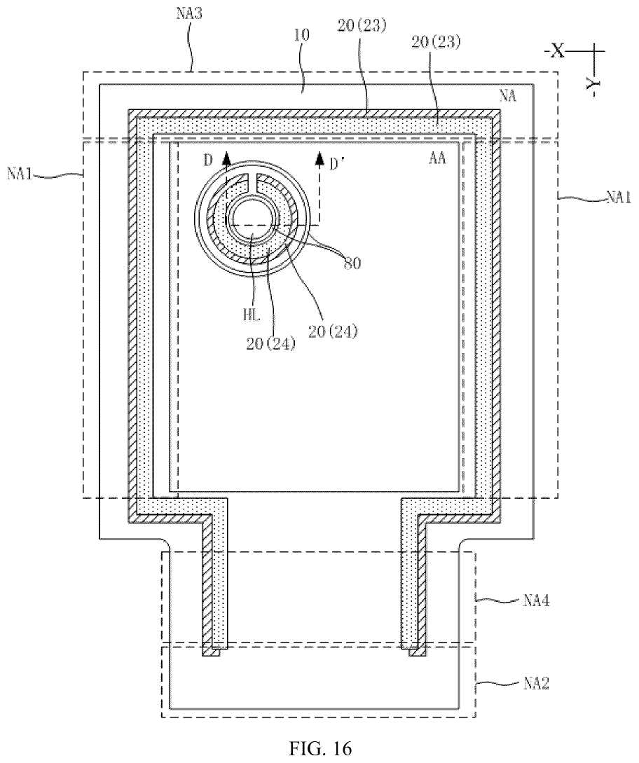

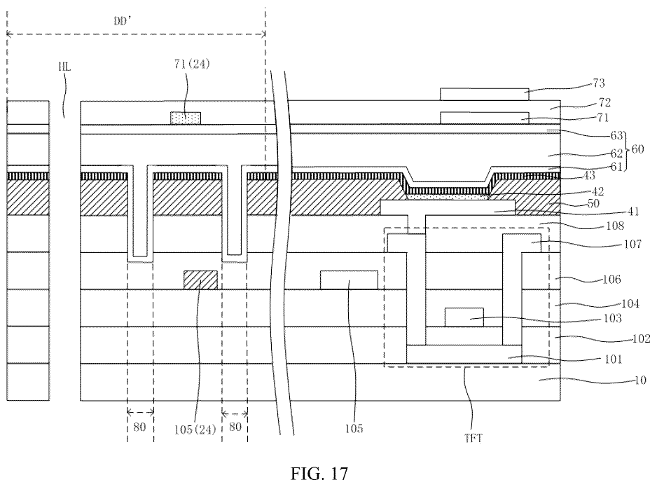

In some embodiments, to form the opening region HL of the display panel, a through-hole is formed by completely removing the substrate 10 and the structural layer thereon in the opening region HL. This may easily create a path for water vapor intrusion. Therefore, a moisture barrier portion 80 may be formed to surround the opening region HL to block water vapor from entering the display panel. Specifically, as shown in FIG. 16 and FIG. 17, FIG. 16 illustrates a schematic structural diagram of yet another display panel according to some embodiments of the present disclosure, and FIG. 17 illustrates a cross-sectional view of the DD′ direction in FIG. 16. As disclosed, the display panel includes a plurality of moisture barrier portions 80 surrounding the opening region HL. The moisture barrier portions 80 are arranged in a nested manner. A crack detection line 20 for the opening may be arranged in a barrier gap between at least one pair of adjacent moisture barrier portions 80. At the location of the moisture barrier portion 80, all metal traces between the encapsulation structure layer 60 and the substrate 10 are in an open-circuit or absent state (optionally, organic material layers such as the planarization layer may also be removed in this region). The purpose of blocking water vapor from corroding the internal wiring of the display panel is achieved through contact between adjacent insulating layers, especially between adjacent inorganic insulating layers. The trench formed by the removal or disconnection of the metal traces at the moisture barrier portion 80 may be filled with the encapsulation structure layer 60. Since this structure is consistent with conventional techniques, further details are omitted. It is understood that by arranging the crack detection line 20 in the barrier gap between two adjacent moisture barrier portions 80, it is possible to both detect cracks in the structural layers of the opening region HL and utilize the routing space efficiently. As shown in FIG. 17, one opening crack detection line 24 may be formed using the capacitor metal layer 105, and the other may be formed using the first touch metal layer 71. The present disclosure does not impose specific limitations in this regard.

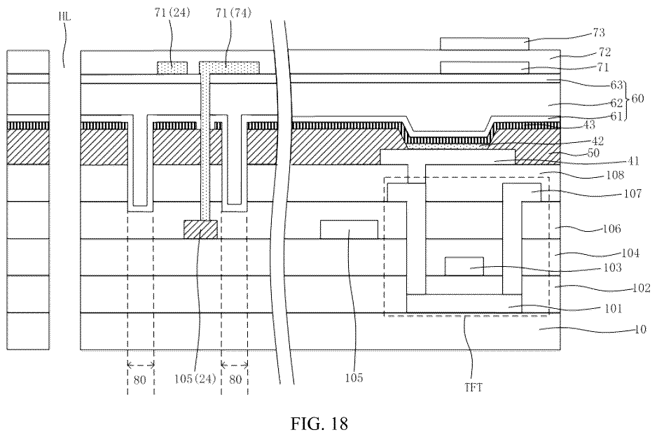

In some embodiments, the opening crack detection line 24 may be arranged in the barrier gap between two adjacent moisture barrier portions 80. The moisture barrier portion 80 has no metal trace or includes open-circuit metal traces (i.e., at least a portion or all of the metal traces in the gate metal layer 103, the capacitor metal layer 105, the source/drain metal layer 107, the anode layer 41, and the cathode layer 43 are either absent or disconnected at this location). Therefore, when the opening crack detection line 24 is fabricated by reusing the gate metal layer 103, the capacitor metal layer 105, and the source/drain metal layer 107, it is not able to be led out and electrically connected to the associated detection circuit via the routing lines of the gate metal layer 103, the capacitor metal layer 105, the source/drain metal layer 107, the anode layer 41, and the cathode layer 43. Accordingly, in some embodiments of the present disclosure, routing of a touch metal layer may be used to lead out the opening crack detection line 24 and electrically connect it to the detection circuit. Referring specifically to FIG. 18, which illustrates a schematic structural diagram of yet another display panel according to some embodiments of the present disclosure. The display panel may include a transistor array layer located on a substrate 10. The transistor array layer includes: a gate metal layer 103, a capacitor metal layer 105, and a source/drain metal layer 107, as well as at least one touch metal layer located on a side of the transistor array layer facing away from the substrate 10. The gate metal layer 103, the capacitor metal layer 105, and the source/drain metal layer 107 have no metal routing corresponding to the moisture barrier portion 80; or portions of the gate metal layer 103, the capacitor metal layer 105, and the source/drain metal layer 107 corresponding to the moisture barrier portion 80 are open circuits. At least one of the gate metal layer 103, the capacitor metal layer 105, and the source/drain metal layer 107 includes an opening crack detection line 24 located at the barrier gap. The touch metal layer includes at least one connection lead-out line 74. At the barrier gap, the opening crack detection line 24 is electrically connected to the connection lead-out line 74 through a via, and the connection lead-out line 74 is electrically connected to a detection circuit.

Continuing as shown in FIG. 18, one opening crack detection line 24 may be formed by reusing the capacitor metal layer 105, while another opening crack detection line 24 may be formed by reusing the first touch metal layer 71. The first touch metal layer 71 may form a connection lead-out line 74, and the connection lead-out line 74 is electrically connected to the opening crack detection line 24 formed from the capacitor metal layer 105 through a via, such that the opening crack detection line 24 is electrically connected to a detection circuit. Additionally, the connection lead-out line 74 may also be formed by reusing the second touch metal layer 73, which is not particularly limited in the present disclosure. Moreover, the opening crack detection line 24 formed from the first touch metal layer 71 may be drawn out and electrically connected to the detection circuit via the connection lines formed in the first touch metal layer 71.

In some embodiments of the present disclosure, at least one of the crack detection lines 20 includes a linear extending segment, facilitating the fabrication of the crack detection line 20. For example, as shown in the continuous edge crack detection line 23 of FIG. 4, at least one side of the display area AA includes an edge crack detection line 23 having a linear extending segment. Alternatively, as shown in the discontinuous edge crack detection line 23 of FIG. 9, on at least one side of the display area AA, an extending segment formed by main detection blocks 203 in the edge crack detection line 23 is a linear extending segment.

Alternatively, in at least one of the crack detection lines 20, at least a portion of an extending segment of the crack detection line 20 is formed as an arcuate extending segment, facilitating the fabrication of the crack detection line 20. Specifically, in the continuous opening crack detection line 24 as shown in FIG. 6, at least a portion of an extending segment of the opening crack detection line 24 is formed as an arcuate extending segment. Alternatively, in the discontinuous opening crack detection line 24 as shown in FIG. 9, an extending segment formed by a portion of adjacent main detection blocks 203 of the opening crack detection line 24 is formed as an arcuate extending segment.

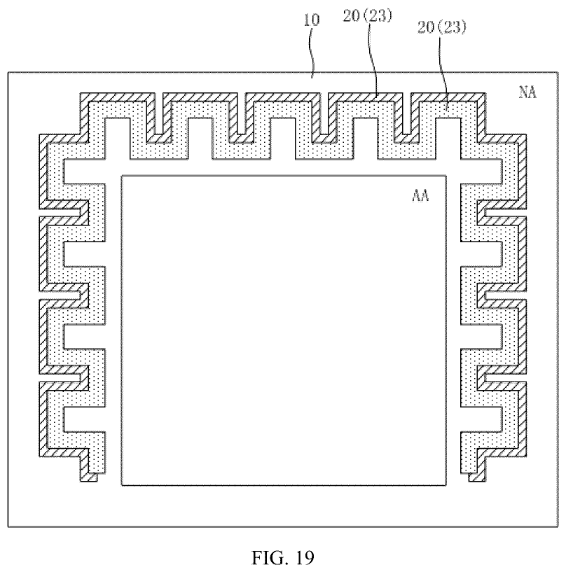

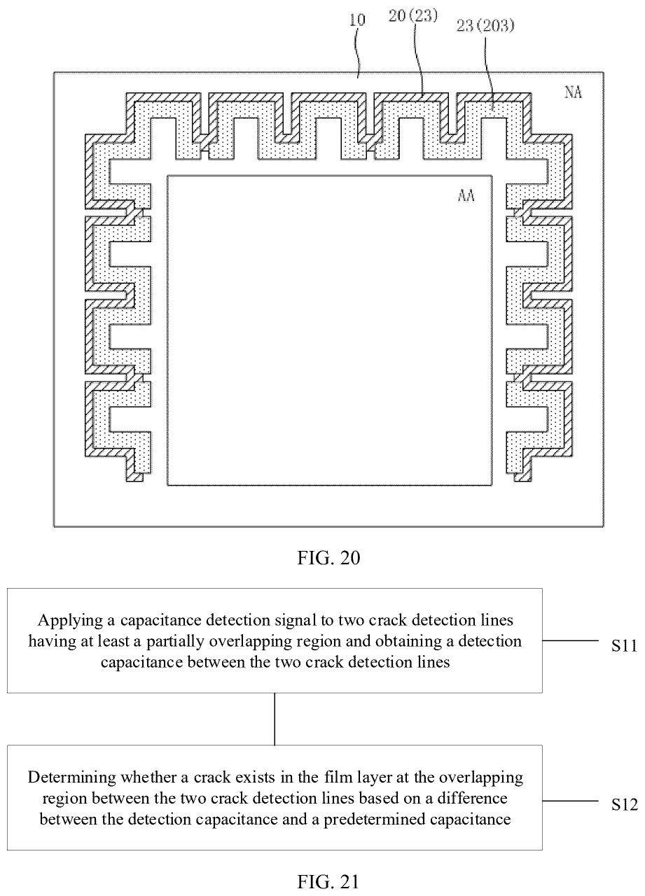

Alternatively, at least one of the crack detection lines 20 may include a segmented zigzag extending segment, which is able to expand the detection coverage of the crack detection line 20 and improve crack detection performance. Taking the edge crack detection line 23 as an example, in the continuous edge crack detection line 23 as shown in FIG. 19, an extending segment of the edge crack detection line 23 is formed as a segmented zigzag extending segment on at least one side of the display region AA. Alternatively, in the discontinuous edge crack detection line 23 as shown in FIG. 20, an extending segment formed by the main detection blocks 203 of the edge crack detection line 23 is formed as a segmented zigzag extending segment on at least one side of the display region AA.

Based on the same inventive concept, the present disclosure also provides a crack detection method for a display panel. The crack detection method is applicable to any of the display panels described above. Referring to FIG. 21, the method may include the following steps:

S11. Applying a capacitance detection signal to two crack detection lines 20 having at least a partially overlapping region and obtaining a detection capacitance between the two crack detection lines 20.

S12. Determining whether a crack exists in the film layer at the overlapping region between the two crack detection lines 20 based on a difference between the detection capacitance and a predetermined capacitance.

In some embodiments, among the two crack detection lines 20 having at least a partially overlapping region, one crack detection line 20 includes a plurality of main detection blocks 203 segmented along an extending direction thereof. The plurality of main detection blocks 203 have at least a partially overlapping region with the other crack detection line 20 in the first direction Z. The step of obtaining the detection capacitance between the two crack detection lines 20 may include: applying a capacitance detection signal to the two crack detection lines 20, where the capacitance detection signal includes an AC signal applied to the other crack detection line 20; and obtaining the detection capacitance between the main detection blocks 203 and the other crack detection line 20. It is then determined whether a crack exists in the film layer at the overlapping region between the main detection blocks 203 and the other crack detection line 20 based on a difference between the detection capacitance and a predetermined capacitance.

That is, according to the technical solution of the present disclosure, in the case where two crack detection lines 20 have at least a partially overlapping region, the capacitance detection signal may be an AC signal applied to one of the crack detection lines 20, while the other crack detection line 20 is used to output the detection capacitance. For example, in the crack detection circuit shown in FIG. 3, between two continuous edge crack detection lines 23, an AC signal may be applied to either of the edge crack detection lines 23, and the detection capacitance may be obtained via the other edge crack detection line 23. The presence of a crack in the film layer between the two edge crack detection lines 23 may be determined based on a difference between the detection capacitance and the predetermined capacitance. In addition, the technical solution of the present disclosure does not require switching transistors on or off to apply the detection signal (e.g., the capacitance or resistance detection signal) to the crack detection line 20. As such, the influence of factors such as transistor leakage current is avoided, improving the stability of the signal applied to the crack detection line 20 and ensuring higher accuracy of crack detection.

Alternatively, as shown in FIG. 8, a crack detection circuit includes: one continuous edge crack detection line 23, and one edge crack detection line 23 segmented into a first detection line 201 and a second detection line 202. An AC signal may be applied to the continuous edge crack detection line 23, and respective detection capacitances may be obtained via the first detection line 201 and the second detection line 202. Subsequently, based on the differences between the obtained detection capacitances and their respective predetermined capacitances, it may be determined whether a film layer between the first detection line 201 and the continuous edge crack detection line 23 has a crack and whether a film layer between the second detection line 202 and the continuous edge crack detection line 23 has a crack. Similarly, when an opening crack detection line 24 is segmented into a first detection line 201 and a second detection line 202, and both the first detection line 201 and the second detection line 202 have overlapping regions with a continuous opening crack detection line 24, the same approach of applying a capacitance detection signal may be employed for crack detection.

Alternatively, as shown in FIG. 9, a crack detection circuit includes: one continuous edge crack detection line, and one edge crack detection line 23 segmented into a plurality of main detection blocks 203. An AC signal may be applied to the continuous edge crack detection line 23, and respective detection capacitances may be obtained via each main detection block 203. Then, based on the differences between the obtained detection capacitances and their respective predetermined capacitances, it may be determined whether the film layers between different main detection blocks 203 and the continuous edge crack detection line 23 have cracks. Similarly, when an opening crack detection line 24 is segmented into a plurality of main detection blocks 203, and all the main detection blocks 203 have overlapping regions with a continuous opening crack detection line 24, the same approach of applying a capacitance detection signal may be employed for crack detection.

Alternatively, as shown in FIG. 10, a crack detection circuit includes: one edge crack detection line 23 segmented into a first detection line 201 and a second detection line 202, and another edge crack detection line 23 segmented into a plurality of main detection blocks 203. AC signals may be applied to the first detection line 201 and the second detection line 202, and respective detection capacitances may be obtained via each main detection block 203. Subsequently, based on the differences between the obtained detection capacitances and their respective predetermined capacitances, it may be determined whether the film layers between different main detection blocks 203 and the first detection line 201, as well as between different main detection blocks 203 and the second detection line 202, have cracks. Similarly, when an opening crack detection line 24 is segmented into a plurality of main detection blocks 203, and all the main detection blocks 203 have overlapping regions with an opening crack detection line 24 segmented into a first detection line 201 and a second detection line 202, the same approach of applying a capacitance detection signal may be employed for crack detection.

Alternatively, as shown in FIG. 11, a crack detection circuit includes: one edge crack detection line 23 segmented into a plurality of main detection blocks 203, and another edge crack detection line 23 segmented into a plurality of auxiliary detection blocks 204. An AC signal may be applied to the main detection blocks 203, and respective detection capacitances may be obtained via the auxiliary detection blocks 204. Or alternatively, an AC signal may be applied to the auxiliary detection blocks 204, and respective detection capacitances may be obtained via the main detection blocks 203. Then, based on the differences between the obtained detection capacitances and their respective predetermined capacitances, it may be determined whether the film layers between different main detection blocks 203 and corresponding auxiliary detection blocks 204 have cracks. Similarly, when an opening crack detection line 24 is segmented into a plurality of main detection blocks 203, and all the main detection blocks 203 have overlapping regions with an opening crack detection line 24 segmented into a plurality of auxiliary detection blocks 204, the same approach of applying a capacitance detection signal may be employed for crack detection.

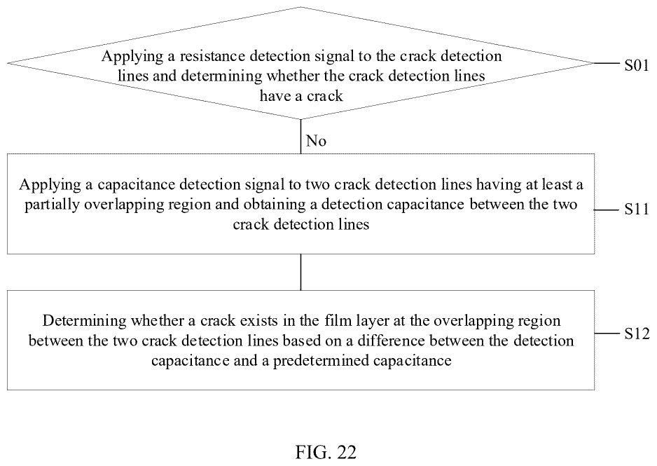

Further, prior to performing capacitance detection using the crack detection circuit, the crack detection line 20 may be tested for potential disconnection. As shown in FIG. 22, a flowchart of another crack detection method is provided according to some embodiments of the present disclosure. Specifically, before step S11, that is, before applying the capacitance detection signal to the crack detection lines 20, the method may further include:

S01: Applying a resistance detection signal to the crack detection lines 20 and determining whether the crack detection lines 20 have a crack.

When no crack is detected, the capacitance detection signal is applied to two crack detection lines 20 having at least a partially overlapping region. Where, the resistance detection signal may be a fixed voltage signal. When a fixed voltage signal is applied to one end of the crack detection line 20 and the crack detection line 20 is not broken, the other end of the crack detection line 20 will detect that the total resistance of the crack detection line 20 is a predetermined resistance. When a break exists in the crack detection line 20, the other end of the crack detection line 20 will detect an infinite resistance. Therefore, by initially determining whether the crack detection line 20 is broken, the reliability of the crack detection is improved.

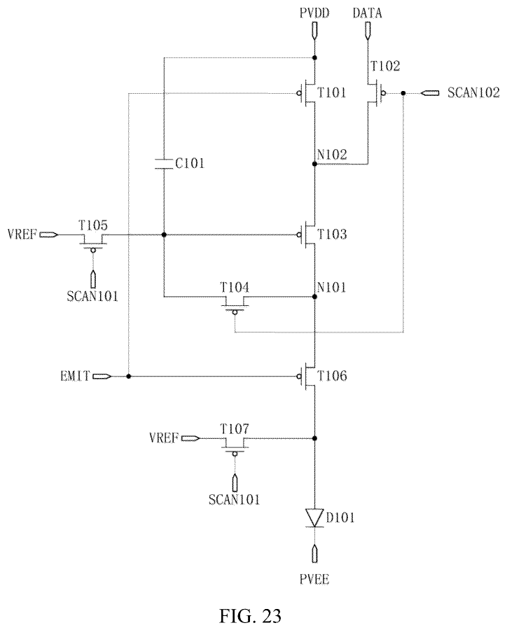

In some embodiments of the present disclosure, the resistance detection signal may reuse the power supply voltage, cathode voltage, or reference voltage in the display panel. FIG. 23 illustrates a schematic diagram of a pixel circuit according to some embodiments of the present disclosure. The display panel includes a pixel circuit electrically connected to a light-emitting diode D101, and the pixel circuit may be a 7T1C circuit. The present disclosure does not make specific restrictions on this, and in some other embodiments, the pixel circuit may also include other numbers of transistors and capacitors. The pixel circuit includes: a first transistor T101, a second transistor T102, a third transistor T103, a fourth transistor T104, a fifth transistor T105, a sixth transistor T106, a seventh transistor T107, a storage capacitor C101, the light-emitting diode D101, a first scan signal terminal SCAN101, a second scan signal terminal SCAN102, a light emission control signal terminal EMIT, a data signal terminal DATA, a power supply voltage terminal PVDD, a cathode voltage terminal PVEE, a reference voltage terminal VREF, a first node N101, and a second node N102. The third transistor T103 is configured to drive the light-emitting diode D101 to emit light. As disclosed, the power supply voltage is the voltage output by the power supply voltage terminal PVDD, the cathode voltage is the voltage output by the cathode voltage terminal PVEE, and the reference voltage is the voltage output by the reference voltage terminal VREF.

It should be noted that the resistance detection signal is not limited to the power supply voltage, cathode voltage, or reference voltage of the display panel as described above. The resistance detection signal may also reuse other fixed voltages in the display panel or may be a fixed voltage independently output by the detection circuit. The present disclosure is not limited in this regard.

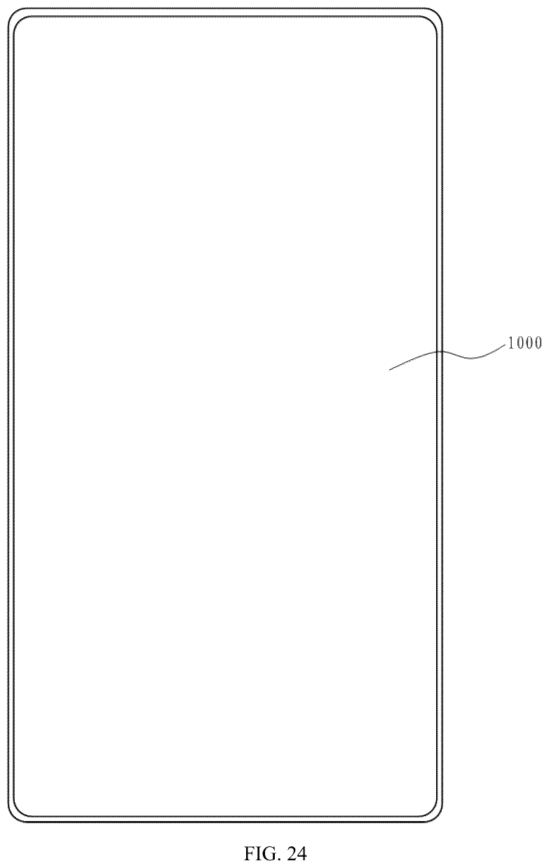

Based on the same inventive concept, some embodiments of the present disclosure further provide an electronic device. Referring to FIG. 24, a schematic diagram of an electronic device is illustrated according to some embodiments of the present disclosure. As shown, the electronic device 1000 includes a display panel provided by any of the embodiments described above.

In some embodiments, the electronic device 1000 may be a mobile terminal, a notebook, a tablet computer, a desktop computer, a wearable device, or an in-vehicle display device. The present disclosure is not limited in this regard.

In summary, some embodiments of the present disclosure provide a display panel, a crack detection method for the display panel, and an electronic device. The display panel includes: a substrate; and a crack detection circuit located on one side of the substrate. Where, the crack detection circuit includes at least two crack detection lines arranged sequentially in a first direction, and adjacent crack detection lines are electrically insulated from each other. In the first direction, any one of the crack detection lines has at least a partially overlapping region with at least one of the other crack detection lines. The first direction is a direction perpendicular to a plane where the display panel is located.

As described above, the crack detection circuit provided by the embodiments of the present disclosure includes crack detection lines that are at least partially overlapped in the first direction. Therefore, when the crack detection circuit is used for crack detection, a change in capacitance between two overlapping crack detection lines may be used to determine whether a film layer between the two crack detection lines has a crack, thereby completing the crack detection process of the display panel. The technical solution provided by the embodiments of the present disclosure enables detection of cracks in intermediate film layers between different crack detection lines, thereby improving the effectiveness of crack detection in the display panel. Additionally, the crack detection circuit has a simple structure and occupies only a small amount of effective routing area in the display panel.

In the description of the present disclosure, it should be understood that the terms such as “center,” “longitudinal,” “lateral,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise,” “axial,” “radial,” “circumferential,” and the like, indicate positional or directional relationships based on those shown in the accompanying drawings. They are merely for the purpose of describing the embodiments of the present disclosure and simplifying the description, rather than indicating or implying that the referenced devices or elements must have a specific orientation or be configured or operated in a specific orientation. Therefore, such terms should not be construed as limiting the present disclosure.

Furthermore, terms such as “first” and “second” are used solely for descriptive purposes and should not be interpreted as indicating relative importance or implying the number of technical features described. Accordingly, features identified as “first” or “second” may expressly or implicitly include one or more such features. In the description of the present disclosure, the term “a plurality of” means at least two, such as two or three, unless explicitly stated otherwise.

In the present disclosure, unless otherwise expressly specified or limited, terms such as “mount,” “connect,” “couple,” and “fix” should be interpreted broadly. For example, they may refer to fixed connections, detachable connections, integral connections, mechanical connections, electrical connections, or communications between components. Such terms may also refer to direct connections or indirect connections through intermediate components, or interactions between components, unless otherwise clearly specified. The specific meanings of these terms in the present disclosure may be understood by those of ordinary skill in the art based on the particular context.

In the present disclosure, unless otherwise expressly specified or limited, when a first feature is described as being “on” or “under” a second feature, it may refer to the first and second features being in direct contact, or indirectly connected through an intermediate medium. Moreover, “on,” “above,” and “over” may refer to the first feature being directly above, obliquely above, or simply at a higher elevation than the second feature. Similarly, “under,” “below,” and “beneath” may refer to the first feature being directly below, obliquely below, or simply at a lower elevation than the second feature.

In the present disclosure, expressions such as “in one embodiment,” “in some embodiments,” “for example,” “illustrative example,” or “specific example” are intended to indicate that specific features, structures, materials, or characteristics described in connection with the embodiment or example are included in at least one embodiment or example of the present disclosure. The use of such phrases does not necessarily refer to the same embodiment or example. Further, various features, structures, materials, or characteristics described may be combined in any suitable manner in one or more embodiments or examples. Moreover, to the extent there is no conflict, those skilled in the art may combine and integrate the features of different embodiments or examples described in the present specification.

Although various embodiments of the present disclosure have been shown and described above, it is understood that such embodiments are illustrative only and not to be construed as limiting the present disclosure. Those of ordinary skill in the art may make changes, modifications, substitutions, or variations to the embodiments described above within the scope of the present disclosure.

What is claimed is:

1. A display panel, comprising: a substrate, and a crack detection circuit located on one side of the substrate, wherein
the crack detection circuit comprises at least two crack detection lines sequentially arranged in a first direction, and adjacent crack detection lines of the at least two crack detection lines are insulated from each other; and
any one crack detection line of the at least two crack detection lines has at least a partially overlapping region with at least one other crack detection line of the at least two crack detection lines in the first direction, wherein the first direction is perpendicular to a plane of the display panel.

2. The display panel according to claim 1, wherein at least one crack detection line of the at least two crack detection lines is a continuous detection line.

3. The display panel according to claim 1, wherein
at least one crack detection line of the at least two crack detection lines comprises a first detection line and a second detection line segmented along an extending direction of the at least one crack detection line, wherein
the first detection line has at least a partially overlapping region with at least one other crack detection line of the at least two crack detection lines in the first direction, and the second detection line has at least a partially overlapping region with at least one other crack detection line of the at least two crack detection lines in the first direction.

4. The display panel according to claim 1, wherein
one crack detection line, among the at least two crack detection lines having at least a partially overlapping region, comprises a plurality of main detection blocks segmented along an extending direction of the one crack detection line; and
the plurality of main detection blocks have at least a partially overlapping region with one other crack detection line of the at least two crack detection lines in the first direction.

5. The display panel according to claim 4, wherein
the one other crack detection line is a continuous detection line; or,
the one other crack detection line comprises a first detection line and a second detection line segmented along an extending direction of the one other crack detection line, wherein
the first detection line has at least a partially overlapping region with at least a portion of the plurality of main detection blocks in the first direction, and the second detection line has at least a partially overlapping region with a remaining portion of the plurality of main detection blocks in the first direction; or,
the one other crack detection line comprises a plurality of auxiliary detection blocks segmented along the extending direction of the one other crack detection line, wherein
one auxiliary detection block of the plurality of auxiliary detection blocks has at least a partially overlapping region with one main detection block of the plurality of main detection blocks in the first direction.

6. The display panel according to claim 1, further comprising: a transistor array layer located on the substrate, wherein
the transistor array layer comprises: a gate metal layer, and a source/drain metal layer; and
the gate metal layer and the source/drain metal layer respectively comprise one crack detection line of the at least two crack detection lines.

7. The display panel according to claim 1, further comprising: a transistor array layer located on the substrate, wherein
the transistor array layer comprises: a gate metal layer, a capacitor metal layer, and a source/drain metal layer; and
at least two of the gate metal layer, the capacitor metal layer, and the source/drain metal layer respectively comprise one crack detection line of the at least two crack detection lines.

8. The display panel according to claim 1, further comprising: a transistor array layer located on the substrate, and at least one touch metal layer located on a side of the transistor array layer away from the substrate, wherein
the transistor array layer comprises: a gate metal layer, a capacitor metal layer, and a source/drain metal layer; and
at least two of the gate metal layer, the capacitor metal layer, the source/drain metal layer, and the touch metal layer respectively comprise one crack detection line of the at least two crack detection lines.

9. The display panel according to claim 1, further comprising: a display region, and a non-display region located outside the display region, wherein
the at least two crack detection lines comprise an edge crack detection line located in the non-display region, and the edge crack detection line extends along an edge of the display region; and
any one edge crack detection line has at least a partially overlapping region with at least one other edge crack detection line in the first direction.

10. The display panel according to claim 9, wherein
the non-display region comprises: a chip bonding region, and a bending region located between the chip bonding region and the display region; and
the edge crack detection line extends at least to the bending region.

11. The display panel according to claim 1, further comprising: an opening region located within a display region, wherein
the at least two crack detection lines comprise an opening crack detection line located in the display region;
the opening crack detection line is arranged to surround the opening region; and
any one opening crack detection line has at least a partially overlapping region with at least one other opening crack detection line in the first direction.

12. The display panel according to claim 11, further comprising: at least two moisture barrier portions surrounding the opening region, wherein
the at least two moisture barrier portions are nested; and
the opening crack detection line is arranged in a barrier gap between at least one pair of adjacent moisture barrier portions of the at least two moisture barrier portions.

13. The display panel according to claim 12, further comprising: a transistor array layer located on the substrate, and at least one touch metal layer located on a side of the transistor array layer away from the substrate, wherein
the transistor array layer comprises: a gate metal layer, a capacitor metal layer, and a source/drain metal layer;
the gate metal layer, the capacitor metal layer, and the source/drain metal layer have no metal routing at locations corresponding to the at least two moisture barrier portions, or portions of the gate metal layer, the capacitor metal layer, and the source/drain metal layer corresponding to the at least two moisture barrier portions are open circuits;
at least one of the gate metal layer, the capacitor metal layer, and the source/drain metal layer comprises one opening crack detection line located in the barrier gap;
the at least one touch metal layer comprises at least one connection lead-out line; and
in the barrier gap, the opening crack detection line is electrically connected to the at least one connection lead-out line through a via.

14. The display panel according to claim 1, wherein
at least a portion of an extending segment of at least one of the at least two crack detection lines, is in a form of a linear extending segment, an arc-shaped extending segment, or a segmented zigzag extending segment.

15. An electronic device, comprising a display panel, wherein the display panel comprises: a substrate, and a crack detection circuit located on one side of the substrate, wherein
the crack detection circuit comprises at least two crack detection lines sequentially arranged in a first direction, and adjacent crack detection lines of the at least two crack detection lines are insulated from each other; and
any one crack detection line of the at least two crack detection lines has at least a partially overlapping region with at least one other crack detection line of the at least two crack detection lines in the first direction, wherein the first direction is perpendicular to a plane of the display panel.

16. The electronic device according to claim 15, wherein
at least one crack detection line of the at least two crack detection lines comprises a first detection line and a second detection line segmented along an extending direction of the at least one crack detection line, wherein
the first detection line has at least a partially overlapping region with at least one other crack detection line of the at least two crack detection lines in the first direction, and the second detection line has at least a partially overlapping region with at least one other crack detection line of the at least two crack detection lines in the first direction.

17. A crack detection method for a display panel, comprising:
applying a capacitance detection signal to two crack detection lines having at least a partially overlapping region, and obtaining a detection capacitance between the two crack detection lines; and
determining whether a film layer in an overlapping region between the two crack detection lines has a crack based on a difference between the detection capacitance and a predetermined capacitance.

18. The crack detection method according to claim 17, wherein, before applying the capacitance detection signal to the two crack detection lines, the crack detection method further comprises:
applying a resistance detection signal to the two crack detection lines and determining whether the two crack detection lines have a crack; and,
applying, when no crack is present, the capacitance detection signal to the two crack detection lines having at least a partially overlapping region.

19. The crack detection method according to claim 18, wherein the resistance detection signal is reused from a power supply voltage, a cathode voltage, or a reference voltage in the display panel.

20. The crack detection method according to claim 17, wherein,
among the two crack detection lines having at least a partially overlapping region, one crack detection line comprises a plurality of main detection blocks segmented along an extending direction of the one crack detection line, the plurality of main detection blocks having at least a partially overlapping region with an other crack detection line in a first direction; and
obtaining the detection capacitance between the two crack detection lines comprises:
applying the capacitance detection signal to the two crack detection lines, wherein the capacitance detection signal comprises an alternating current signal applied to the other crack detection line; and
obtaining the detection capacitance between the plurality of main detection blocks and the other crack detection line and determining whether the film layer in the overlapping region between the plurality of main detection blocks and the other crack detection line has a crack based on a difference between the detection capacitance and a predetermined capacitance.
